(19) United States
(12) Patent Application Publication
(10) Pub. No.: US 2007/0269283 A1
(43) Pub. Date: Nov. 22, 2007

(54) Chassis rack

(76) Inventors: Peter Klestoff, Burlingame, CA (US); Andrzej Waluto, Walnut Creek, CA (US)

Correspondence Address: PETER KLESTOFF, 1136 BALBOA AVE., BURLINGAME, CA, 94010, US

(21) Appl. No.: 11/285,880

(22) Filed: May 22, 2006

(51) Int. Cl. H05K 7/20; B60P 3/06

(52) U.S. Cl. 410/30; 410/65

(57) ABSTRACT

At present in container yards, chassis are stacked on top of each other, tire on tire, causing the tires to bind and making the whole stack immobile. Stacking is used to save space. The chassis rack is a welded apparatus, made from structural steel tubing. It is used to separate the bottom chassis on the ground from the one above. By separating them, the tires are freed and the chassis above is moved up and back. By using the chassis rack, the whole stack can be moved around the yard.

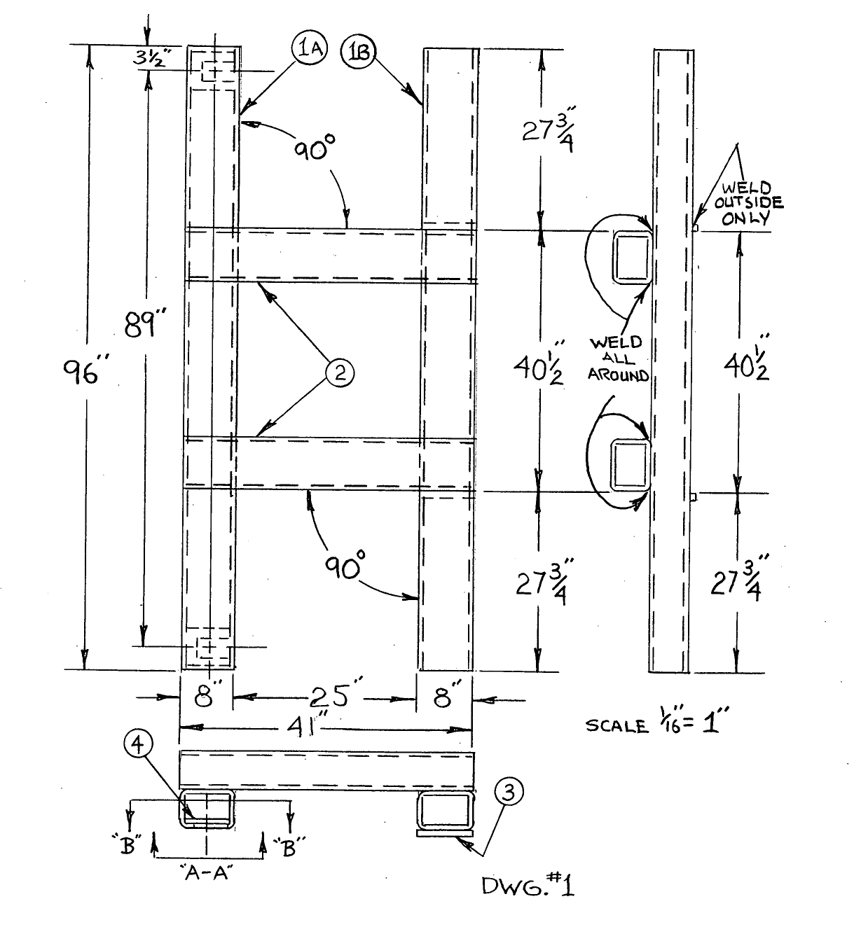

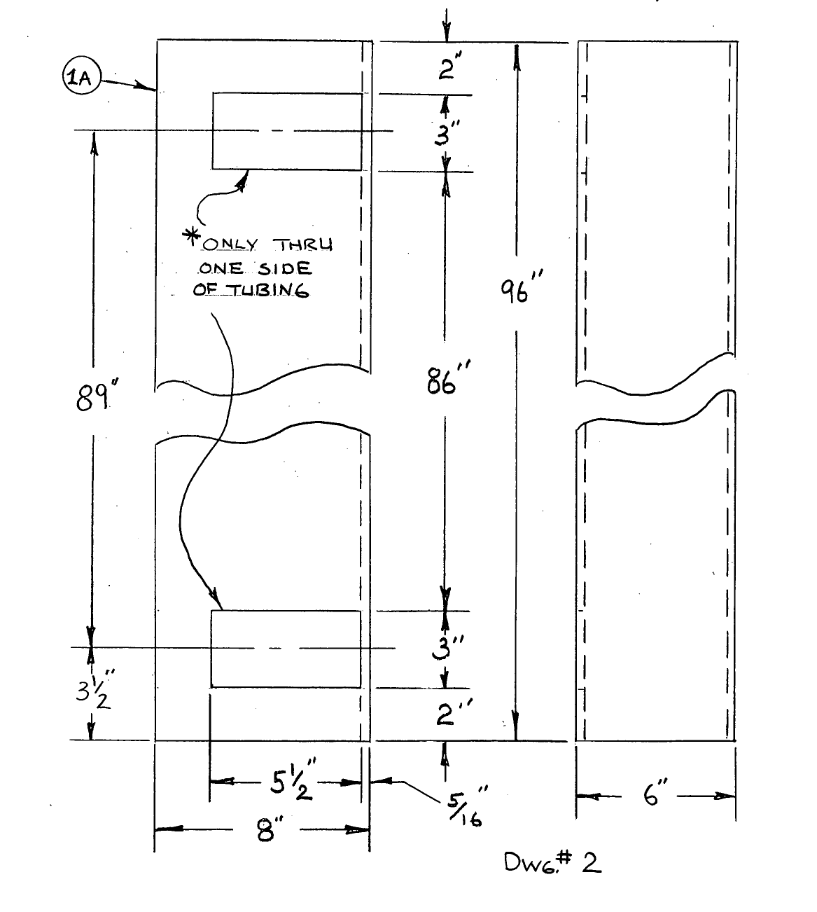

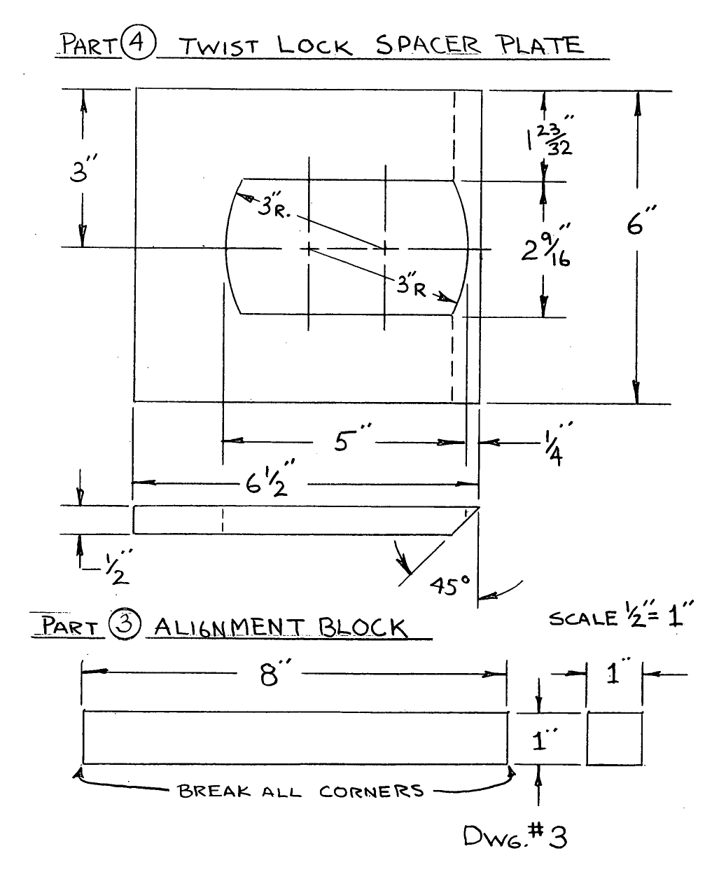

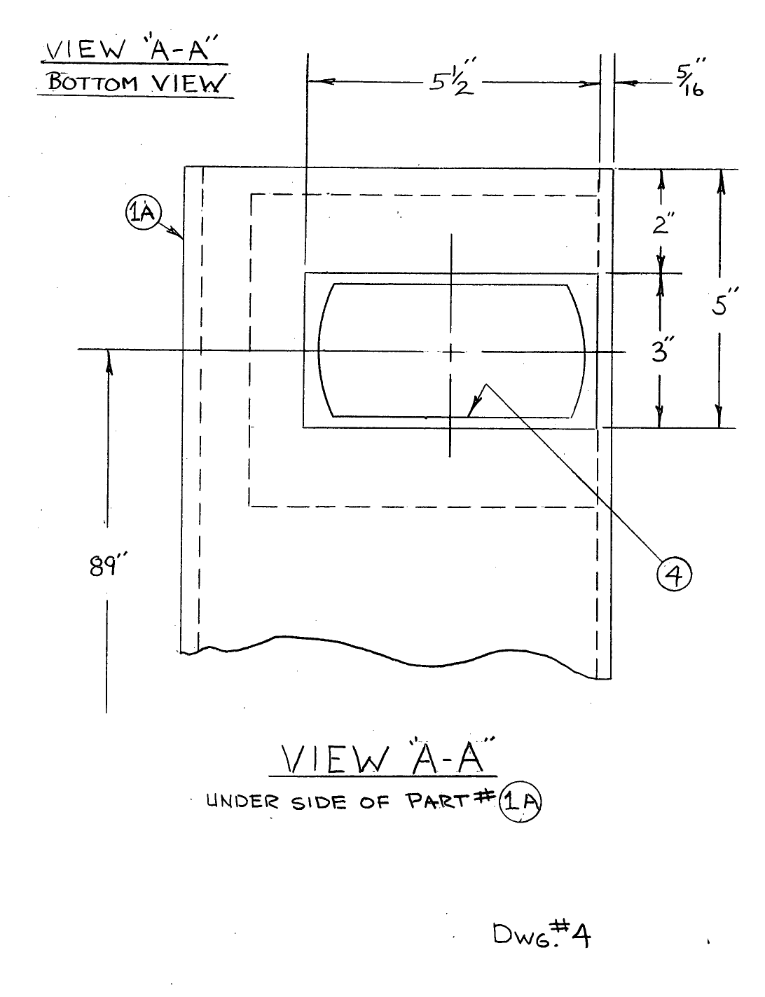

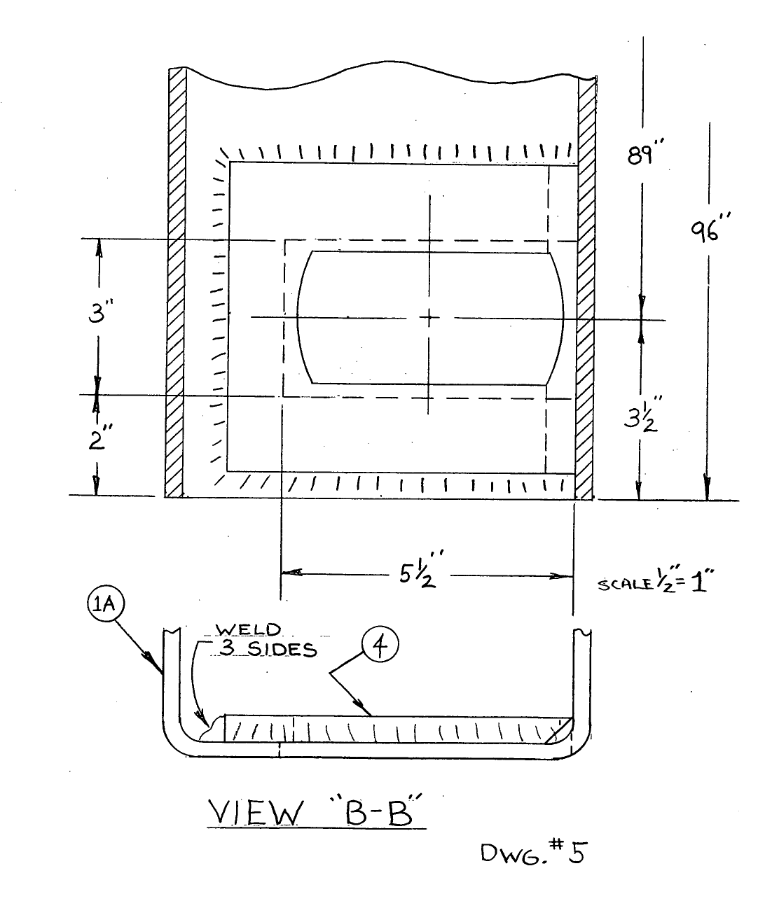

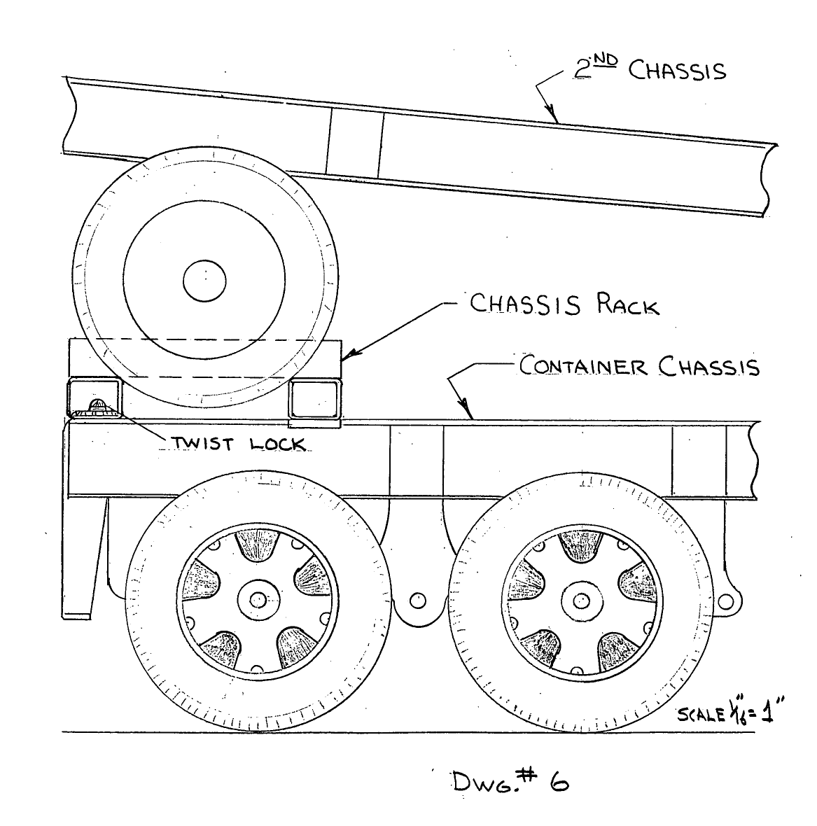

### BACKGROUND FOR INVENTION

Over the years, I have observed container chassis that are stacked up to five high, in order to economize on space. Stacking chassis wheel on wheel makes the stack immobile, because it binds the wheels of the bottom chassis.

Rows and rows of chassis are stacked in one area. If a specific chassis is needed, a forklift is used to unstack each chassis, beginning with the front row and continuing this process until you reach the specific chassis needed. This is a labor intensive and time consuming process which is then repeated as needed. Also, the front of each stacked chassis is pushed forward, making it impossible to move the bottom chassis with a yard tractor, even if it were mobile.

While observing the stacking and unstacking of chassis, I came to the conclusion that there had to be a better way to make these stacked chassis mobile. If the wheels of the second chassis were to be clear of the bottom chassis, and the front of that chassis is even to the bottom chassis, then the yard tractor would be able to move the entire stack.

The Chassis rack, placed on the back end of the bottom chassis, then locked in place with chassis twistlocks, would provide the spacing needed to clear the wheels of that chassis. When the second chassis is stacked on top of the rack, the wheels are clear of the bottom chassis. Also, the front of the second chassis is even with the bottom, allowing access to the bottom chassis by a yard tractor. The additional stacked chassis would be stacked wheel on wheel.

### ADVANTAGES

In container terminals, trucking companies and other businesses that use large amounts of chassis in their operation, stack and unstack chassis to optimize space. The chassis are usually stacked wheel on wheel up to 5 high. This stacking system makes the stack immobile, since the wheels rub against each other.

The Chassis rack placed between the bottom and the 2^{nd} chassis solves this problem by making the second chassis clear the wheels of the bottom chassis. It then makes the stack moveable with a yard and/or road tractor. The third and fourth chassis would be stacked wheel on wheel.

Moving stacks of chassis as a unit instead of one by one saves labor and time. Specific chassis could easily be made available without unstacking every chassis in its way. This type of stack can then be moved within the terminal to make space and over the road from one location to another, i.e., repositioning of chassis. The existing stacks could be moved off the terminal by outside truckers and easily unstacked with a forklift. Securing/lashing would still have to be done before moving them over the road. A stack of 3 chassis is low enough (approximately 13′2″ high) to clear any overpasses on the freeways.

The present stacking system for repositioning over the road is more complicated, labor intensive, and time consuming, requiring some of the chassis to be upside down. The stacks still need to be banded and/or lashed for movement over the road at only two high.

### OPERATION

The chassis rack is placed on the back of a container chassis by using a forklift or crane and is locked into place by the twist locks that are on the chassis. (Twist locks are on all container chassis. They are used to lock the container to the chassis for transportation). The twist locks on the chassis go through the cut-out in part 1A of the chassis rack and the alignment blocks on part 1B, aligning the chassis rack to the sides of the chassis. The twist lock levers are rotated 90 degrees to secure the rack to the chassis.

After the chassis rack is secured to the chassis, the 2^{nd} chassis can be stacked on top of it. The second chassis is stacked so that the forward wheels fit between part 1A and part 1B, as shown in drawing # 6, on page 12A. After the second chassis is stacked on top of the bottom chassis by using the chassis rack, the next chassis can be stacked the usual way, tires on tires.

### MATERIAL LIST

| | | | Part |
|---|---|---|---|
| Qty | Material | Size | Number |
| 1 | Rectangular Steel Tubing | 6″ × 8″ × .312 wall | (#1A) |
| | | thickness × 96″ | |
| 1 | Rectangular Steel Tubing | 6″ × 8″ × .312 wall | (#1B) |
| | | thickness × 96″ | |
| 2 | Rectangular Steel Tubing | 6″ × 8″ × .312 wall | (#2) |
| | | thickness × 41″ | |
| 2 | Cold Roll Steel | 1″ × 1″ × 8″ square stock | (#3) |
| | (Alignment Blocks) | | |
| 2 | Cold Roll Steel Plate | 6″ × 6½ ″ × ½ ″ thick | (#4) |
| | (Twist Lock Spacer Plates) | steel plate | |

### ASSEMBLY INSTUCTIONS

Take two pieces of 6″×6½″×½′ thick steel plate and cut out openings and angles as shown in drawing # 3, on page 9A. This will become part #4.

Take one piece of 6″×8″×96″ steel tubing and cut out openings on both ends as shown in drawing #2 on page 8A. This will become part #1A.

Take part #1A with the rectangular cut-outs and place part #4 inside part #1A and weld together as shown in drawing # 5, on page 11A.

Take another piece of 6″×8″×96″ steel tubing and weld the alignment blocks (part #3) to the steel tubing on three sides, as shown on drawing #1, page 7A. Do not weld the two inside areas facing each other. This will become part #1B with part #3 welded to it.

Place part #1A and part #1B, 25″ apart, making sure they are parallel and even to each other. Make sure that parts #1A and #1B are placed correctly, as shown on drawing #1, page 7A, with the twist lock cut-outs and alignment blocks facing down. Place both parts #2 on top of parts #1A and #1B keeping with the dimensions shown on drawing #1, on page 7A, and clamp together. Weld parts #1A, #1B and both parts #2 with at least a ½″ bead of weld with full penetration all the way around parts #1A, #1B and both parts #2.

Sandblast and paint.

### EXPLANATION OF DRAWING #1

Drawing #1 on page 7A shows the chassis rack completely assembled and welded. The drawing also shows references to part numbers, assembly dimensions and refers to two views that are shown on (new) drawing #4 on page 10A and drawing #5 on page 11A.

### EXPLANATION OF DRAWING #2

Drawing #2 on page 8A shows the details for the twist lock cut-outs for part #1A

### EXPLANATION OF DRAWING #5

Drawing #5 on page 11A shows view “B-B” from the completed assembly drawing #1 on page 7A. The drawing also shows the placement and welding detail of the twist-lock spacer plate, part #4 to part #1A.

### EXPLANATION OF DRAWING #6

Drawing #6 on page 12A shows where the chassis rack is placed on the container chassis. The drawing also shows the wheels of the second chassis on top of the bottom chassis being supported by the chassis rack.

We claim:

1) The container chassis rack is a piece of equipment, that when set down on the back end of a one high road chassis, supports and separates the rear wheels of the next stacked chassis from the bottom one, thus making it mobile for movement within the container yard or over the road. Instead of the rear axles sitting on top of the bottom chassis, wheel on wheel, and preventing the stack from movement, the chassis rack separates the 2 sets of wheels enough, so that the bottom one can be moved with a road and/or a yard tractor.

2) The chassis rack in claim 1 is a steel-welded structure that cradles the rear wheels of the stacked chassis and keeps the lower and upper wheels from touching and binding. This structure is made of steel to support the weight of the initial stacked chassis, as well as the others, that will be stacked on top of it. These can be stacked 2, 3, or 4 high on top of the bottom chassis.

3) The chassis rack in claim 1 is a steel rack that attaches to the top of the bottom chassis and allows the 2nd chassis to be stacked on top, wheel to wheel, for ease of transportation and/or storage. It is much easier and more cost effective to move the whole stack with a tractor, rather than unstacking the chassis individually, moving them, and having to stack them again, if you need the space for other uses. This is frequently done in a large container yard lacking in space.

4) The chassis rack in claim 1 attaches to the bottom chassis when the precut holes on the bottom rear of the rack is set down on top and aligned to the rear twist locks. The twist locks of the chassis are then turned to keep them locked to the rack. The metal inserts in the precut holes of the rack keep the twist locks snug and are able to stay locked. The front of the rack is set along the center portion of the chassis and aligned by a set of welded metal blocks on each side

5) The chassis rack in claim 1 aligns the 2^{nd} stacked chassis so that the front of the top one is set back enough to allow a road and/or yard tractor to hook up to the bottom one. This gives the tractor the ability to move the stack freely in all directions. Without the rack, the wheels of the top chassis sit in between the bottom wheels. This forces the front end of the top chassis to stick out making it impossible to connect it to a tractor.

6) The chassis rack in claim 1 allows the road and/or yard tractor to move the whole stack of 2, 3, or 4 chassis freely. This saves money in labor, as well as time, when limited space is used for multiple purposes. It is much easier to move the entire stack once with a tractor, rather than handling each chassis individually with a forklift.

7) The chassis rack in claim 1 allows the 3^{rd} and 4^{th} chassis to be stacked wheel on wheel and still leave the whole stack mobile.

8) The chassis rack in claim 1, when used as a separator between the bottom chassis and the 2^{nd} chassis, makes the whole stack freely moveable in a container yard. When necessary to be moved over the road, the stack of chassis would then be properly lashed together, as is customary, for safe transportation.
